(19) United States
(12) Patent Application Publication
(10) Pub. No.: US 2024/0381697 A1
(43) Pub. Date: Nov. 14, 2024

(54) DISPLAY PANEL, METHOD FOR PREPARING DISPLAY PANEL, AND DISPLAY DEVICE

(71) Applicants: Chongqing BOE Display Technology Co., Ltd., Chongqing (CN); BOE Technology Group Co., Ltd., Beijin (CN)

(72) Inventors: Ni YANG, Beijing (CN); Wei ZHANG, Beijing (CN); Rui WANG, Beijing (CN); Hai ZHENG, Beijing (CN)

(21) Appl. No.: 18/258,680

(22) PCT Filed: Jun. 30, 2022
(86) PCT No.: PCT/CN2022/103058

§ 371 Date: Jun. 21, 2023

(51) Int. Cl. H10K 59/122; H10K 59/12; H10K 59/80

(52) U.S. Cl. CPC H10K 59/122; H10K 59/1201; H10K 59/80515

(57) ABSTRACT

The present disclosure provides a display panel. The display panel includes a pixel layer, and the pixel layer includes a pixel electrode layer, an insulated metal layer, a pixel definition layer, an electroluminescence layer and a common electrode layer stacked in sequence. The pixel electrode layer includes a pixel electrode, and the insulated metal layer includes an insulated metal block corresponding to the pixel electrode; the insulated metal block and the pixel definition layer are provided with a pixel opening that exposes the corresponding pixel electrode; an insulated lateral slot that surrounds the pixel opening and opens at the pixel opening, is provided between the insulated metal block and the pixel opening; and the electroluminescence layer covers the pixel opening, and a thickness of the electroluminescence layer is equal to or greater than a thickness of the insulated metal block.

### CROSS-REFERENCE TO RELATED APPLICATIONS

The present application is the U.S. National phase application of International Application No. PCT/CN2022/103058, filed on Jun. 30, 2022, the entire contents of which are hereby incorporated by reference in its entirety.

### TECHNICAL FIELD

The present disclosure relates to the field of display technologies, and in particular, to a display panel, a method for preparing the display panel, and a display device.

### BACKGROUND

With the development of Organic Light-Emitting Diode (OLED) display technology, the market demand for product brightness and power consumption is increasing. Therefore, the application of Tandem OLED is more and more widely demanded.

However, inter-pixel crosstalk is relatively obvious in the Tandem OLED, which affects the display quality of the product.

It should be noted that the above information disclosed in the “BACKGROUND” section is intended only to enhance the understanding of the background of this disclosure, and therefore it may include information that does not constitute prior art known to those of ordinary skill in the art.

### SUMMARY

The present disclosure provides a display panel, a method for preparing the display panel, and a display device.

According to a first aspect of the present disclosure, there is provided a display panel, including a substrate, a driver layer and a pixel layer stacked in sequence; where the pixel layer includes a pixel electrode layer, an insulated metal layer, a pixel definition layer, an electroluminescence layer and a common electrode layer stacked in sequence on a side of the driver layer away from the substrate;
where the pixel electrode layer includes a pixel electrode, and the insulated metal layer includes an insulated metal block corresponding to the pixel electrode; the insulated metal block and the pixel definition layer are provided with a pixel opening that exposes the corresponding pixel electrode; and an insulated lateral slot that surrounds the pixel opening and opens at the pixel opening, is provided between the insulated metal block and the pixel opening; and
the electroluminescence layer covers the pixel opening, and a thickness of the electroluminescence layer in a direction perpendicular to the substrate is equal to or greater than a thickness of the insulated metal block.

According to an embodiment of the present disclosure, an outer edge of the pixel electrode is flush with an outer edge of the corresponding insulated metal block.

According to an embodiment of the present disclosure, the insulated metal block covers an outer edge of the corresponding pixel electrode.

According to an embodiment of the present disclosure, the thickness of the insulated metal block ranges from 100 to 1000 Å.

According to an embodiment of the present disclosure, the insulated metal block includes a metal layer.

According to an embodiment of the present disclosure, the insulated metal block includes a first metal layer and a second metal layer stacked in sequence on a side of the pixel electrode away from the substrate, a metal activity of the second metal layer being weaker than a metal activity of the first metal layer; and
the second metal layer protrudes from the first metal layer at an edge of the insulated metal block close to the insulated lateral slot.

According to an embodiment of the present disclosure, a material of a surface of the pixel electrode layer away from the substrate is a conductive metal oxide.

According to an embodiment of the present disclosure, the electroluminescence layer includes a first organic light-emitting layer, a charge generation layer and a second organic light-emitting layer stacked in sequence on a side of the pixel electrode away from the substrate; and
the charge generation layer is discontinuous at an edge of the pixel opening close to the substrate.

According to an embodiment of the present disclosure, the insulated metal block is in a closed annular structure; and an orthographic projection of the pixel opening corresponding to the pixel electrode on the substrate, is within an orthographic projection of an inner cavity of the insulated metal block corresponding to the pixel electrode on the substrate.

According to a second aspect of the present disclosure, there is provided a display device, including the display panel as described above.

According to a third aspect of the present disclosure, there is provided a method for preparing a display panel, including:
forming a driver layer on a side of a substrate; and
forming a pixel layer on a side of the driver layer away from the substrate, the pixel layer including a pixel electrode layer, an insulated metal layer, a pixel definition layer, an electroluminescence layer and a common electrode layer stacked in sequence on the side of the driver layer away from the substrate; where the pixel electrode layer includes a pixel electrode, and the insulated metal layer includes an insulated metal block corresponding to the pixel electrode; the insulated metal block and the pixel definition layer are provided with a pixel opening that exposes the corresponding pixel electrode; an insulated lateral slot that surrounds the pixel opening and opens at the pixel opening, is provided between the insulated metal block and the pixel opening; and the electroluminescence layer covers the pixel opening, and a thickness of the electroluminescence layer is equal to or greater than a thickness of the insulated metal block.

According to an embodiment of the present disclosure, forming the pixel layer on the side of the driver layer away from the substrate, includes:
forming a pixel electrode material layer and an insulated metal material layer sequentially on the side of the driver layer away from the substrate;
patterning the pixel electrode material layer and the insulated metal material layer to form a pixel electrode and an insulated metal intermediate portion corresponding to and stacked with the pixel electrode;
forming the pixel definition layer on a side of the insulated metal intermediate portion away from the substrate, the pixel definition layer having a pixel top opening that exposes part of the insulated metal intermediate portion;
etching the exposed part of the insulated metal intermediate portion using the pixel definition layer as a mask, and forming a pixel bottom opening and the insulated lateral slot that expose at least part of the pixel electrode, the insulated lateral slot being interconnected to the pixel bottom opening and surrounding the pixel bottom opening; and
forming the electroluminescence layer and the common electrode layer sequentially on a side of the pixel definition layer away from the substrate, the thickness of the electroluminescence layer being equal to or greater than a thickness of the insulated metal material layer.

According to an embodiment of the present disclosure, forming the pixel layer on the side of the driver layer away from the substrate, includes:
forming the pixel electrode layer on the side of the driver layer away from the substrate, the pixel electrode layer including the pixel electrode;
forming an insulated metal intermediate portion corresponding to the pixel electrode on a side of the pixel electrode layer away from the substrate, the insulated metal intermediate portion covering the corresponding pixel electrode;
forming the pixel definition layer on a side of the insulated metal intermediate portion away from the substrate, the pixel definition layer having a pixel top opening that exposes part of the insulated metal intermediate portion;
etching the exposed part of the insulated metal intermediate portion using the pixel definition layer as a mask, and forming a pixel bottom opening and the insulated lateral slot that expose at least part of the pixel electrode, the insulated lateral slot being interconnected to the pixel bottom opening and surrounding the pixel bottom opening; and
forming the electroluminescence layer and the common electrode layer sequentially on a side of the pixel definition layer away from the substrate, the thickness of the electroluminescence layer being equal to or greater than a thickness of the insulated metal intermediate portion.

According to an embodiment of the present disclosure, etching the exposed part of the insulated metal intermediate portion using the pixel definition layer as the mask, includes:
performing wet etching on the insulated metal intermediate portion, and continuing etching the the insulated metal intermediate portion after the insulated metal intermediate portion exposes the pixel electrode until remaining insulated metal intermediate portion shrinks to be within a coverage of the pixel definition layer to form the insulated lateral slot.

According to an embodiment of the present disclosure, before etching the exposed part of the insulated metal intermediate portion using the pixel definition layer as the mask, the method for preparing the display panel further includes:
performing heat treatment on the pixel electrode.

According to an embodiment of the present disclosure, a thickness of the insulated metal intermediate portion ranges from 100 to 1000 Å.

According to an embodiment of the present disclosure, the insulated metal intermediate portion includes a metal layer.

According to an embodiment of the present disclosure, the insulated metal intermediate portion includes a first metal layer and a second metal layer stacked in sequence on a side of the pixel electrode away from the substrate, a metal activity of the second metal layer being weaker than a metal activity of the first metal layer; and
when the exposed part of the insulated metal intermediate portion is etched using the pixel definition layer as the mask, the insulated metal intermediate portion is patterned as the insulated metal block; and the second metal layer protrudes from the first metal layer at an edge of the insulated metal block close to the insulated lateral slot.

According to an embodiment of the present disclosure, the electroluminescence layer includes a first organic light-emitting layer, a charge generation layer and a second organic light-emitting layer stacked in sequence on a side of the pixel electrode away from the substrate; and
when the electroluminescence layer is formed sequentially on a side of the pixel definition layer away from the substrate, the charge generation layer is discontinuous at an edge of the pixel opening close to the substrate.

It should be understood that the above general description and the following detailed descriptions are exemplary and explanatory only and do not limit the present disclosure.

### BRIEF DESCRIPTION OF THE DRAWINGS

The accompanying drawings herein are incorporated into and form part of the specification, show embodiments that are consistent with the present disclosure, and are used in conjunction with the specification to explain the principles of the present disclosure. It will be apparent that the drawings in the following description are only some of embodiments of the present disclosure, and that other drawings may be obtained from them without creative effort by those of ordinary skill in the art.

FIG. 1 is a schematic diagram of a structure of a display panel in one embodiment of the present disclosure.

FIG. 2 is a schematic diagram of a structure of an OLED in one embodiment of the present disclosure.

FIG. 3-1 is a flow diagram of a method for preparing a display panel in one embodiment of the present disclosure.

FIG. 3-2 is a schematic diagram of a process for preparing a pixel layer in one embodiment of the present disclosure.

FIG. 4 is a schematic diagram of a structure of preparing a pixel electrode material layer on a driver substrate in one embodiment of the present disclosure.

FIG. 5 is a schematic diagram of a structure of preparing an insulated metal material layer on the pixel electrode material layer in one embodiment of the present disclosure.

FIG. 6 is a schematic diagram of a structure of patterning the pixel electrode material layer and the insulated metal material layer in one embodiment of the present disclosure.

FIG. 7 is a schematic diagram of a structure of forming a pixel definition material layer that covers a pixel electrode and an insulated metal intermediate portion in one embodiment of the present disclosure.

FIG. 8 is a schematic diagram of a structure of patterning the pixel definition material layer to form a pixel top opening in one embodiment of the present disclosure.

FIG. 9 is a schematic diagram of a structure of patterning the insulated metal intermediate portion to form a pixel bottom opening and an insulated lateral slot in one embodiment of the present disclosure.

FIG. 10-1 is a schematic diagram of a structure of forming an electroluminescence layer and a common electrode layer that cover the pixel opening in one embodiment of the present disclosure.

FIG. 10-2 is a schematic diagram of a structure of forming the electroluminescence layer and the common electrode layer that cover the pixel opening in one embodiment of the present disclosure.

FIG. 11 shows relative position relationships between an inner edge of the pixel definition layer, an inner edge of an insulated metal block, an outer edge of the insulated metal block, and an edge of a pixel electrode in one embodiment of the present disclosure.

FIG. 12 shows relative position relationships between the inner edge of the pixel definition layer, the inner edge of the insulated metal block, the outer edge of the insulated metal block, and the edge of the pixel electrode in one embodiment of the present disclosure.

FIG. 13 is a schematic diagram of a structure of forming a pixel electrode material layer on a driver substrate in one embodiment of the present disclosure.

FIG. 14 is a schematic diagram of a structure of forming an insulated metal material layer on the pixel electrode material layer in one embodiment of the present disclosure.

FIG. 15 is a schematic diagram of a structure of an insulated metal material layer including three metal layers in one embodiment of the present disclosure.

FIG. 16 is a schematic diagram of a structure of patterning the pixel electrode material layer and the insulated metal material layer to form a pixel electrode and an insulated metal intermediate portion in one embodiment of the present disclosure.

FIG. 17 is a schematic diagram of a structure of film layers of the insulated metal intermediate portion in one embodiment of the present disclosure.

FIG. 18 is a schematic diagram of a structure of forming a pixel definition layer in one embodiment of the present disclosure.

FIG. 19 is a schematic diagram of a structure of forming a pixel bottom opening and an insulated lateral slot in one embodiment of the present disclosure.

FIG. 20 is a schematic diagram of a partial structure of a pixel top opening, a pixel bottom opening, and an insulated lateral slot in one embodiment of the present disclosure.

FIG. 21 is a schematic diagram of a structure of forming an electroluminescence layer and a common electrode layer that cover the pixel opening in one embodiment of the present disclosure.

FIG. 22 is a flow diagram of a method for preparing a pixel layer in one embodiment of the present disclosure.

FIG. 23 is a schematic diagram of a structure of forming a pixel electrode layer on a side of a driver substrate in one embodimentd of the present disclosure.

FIG. 24 is a schematic diagram of a structure of forming an insulated metal intermediate portion that covers a pixel electrode in one embodiment of the present disclosure.

FIG. 25 is a schematic diagram of a structure of forming a pixel definition layer in one embodiment of the present disclosure.

FIG. 26 is a schematic diagram of a structure of forming a pixel bottom opening and an insulated lateral slot in one embodiment of the present disclsure.

FIG. 27 is a schematic diagram of a structure of forming an electroluminescence layer and a common electrode layer that cover a pixel opening in one embodiment of the present disclosure.

FIG. 28 shows relative position relationships between an inner edge of the pixel definition layer, an inner edge of an insulated metal block, an outer edge of the insulated metal block, and an edge of a pixel electrode in one embodiment of the present disclosure.

FIG. 29 shows relative position relationships between the inner edge of the pixel definition layer, the inner edge of the insulated metal block, the outer edge of the insulated metal block, and the edge of the pixel electrode in one embodiment of the present disclosure.

### DETAILED DESCRIPTION

Exemplary embodiments will now be described more fully with reference to the accompanying drawings. However, the exemplary embodiments can be implemented in a variety of forms and should not be construed as being limited to the embodiments set forth herein; rather, the provision of these embodiments makes the present disclosure comprehensive and complete and conveys the ideas of the exemplary embodiments to those skilled in the art in a comprehensive manner. The same reference numerals in the drawings indicate the same or similar structures, and thus their detailed description will be omitted. In addition, the accompanying drawings are only schematic illustrations of the present disclosure and are not necessarily drawn to scale.

Although relative terms such as “above” and “below” are used in this specification to describe the relative relationship of one component of the reference sign to another, these terms are used in this specification only for convenience, for example, according to the exemplary direction shown in the accompanying drawings. It should be understood that if the device of the reference sign is flipped so that it is upside down, the component described as being “above” will become the component described as being “below”. When a structure is “on” other structures, it may mean that this structure is integrally formed on other structures, or that this structure is “directly” arranged on other structures, or that this structure is “indirectly” arranged on other structures through another structure.

The terms “one,” “a/an,” and “the/said” are used to indicate the existence of one or more elements/components/etc. The terms “including/comprising” and “having” are used to indicate open-ended inclusion and to mean that additional elements/components/etc. may exist in addition to the listed elements/components/etc. The terms “first,” “second,” and “third” are used as indicator only and are not limitations on the number of objects thereof.

A transistor is a component that includes at least three terminals: a gate electrode, a drain electrode, and a source electrode. The transistor has a channel region between the drain electrode (drain terminal, drain region, or drain) and the source electrode (source terminal, source region or source) and the current can flow through the drain electrode, the channel region, and the source electrode. The channel region is a region through which the current primarily flows.

A structural layer A is on the side of a structural layer B away from the substrate, which can be understood as that the structural layer A is formed on the side of the structural layer B away from the base substrate, and when the structural layer B is a patterned structure, part of the structural layer A may also be located at the same physical height of the structural layer B or below the physical height of the structural layer B, where the substrate is the height reference.

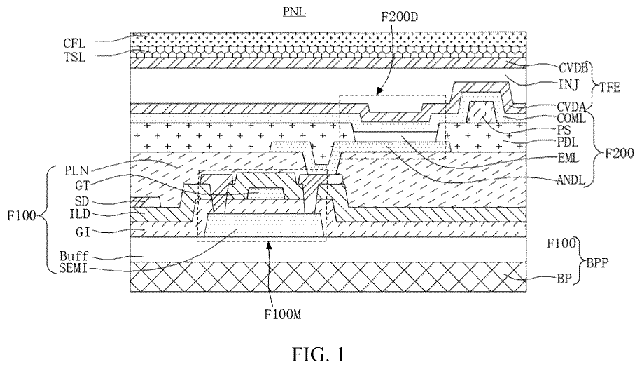

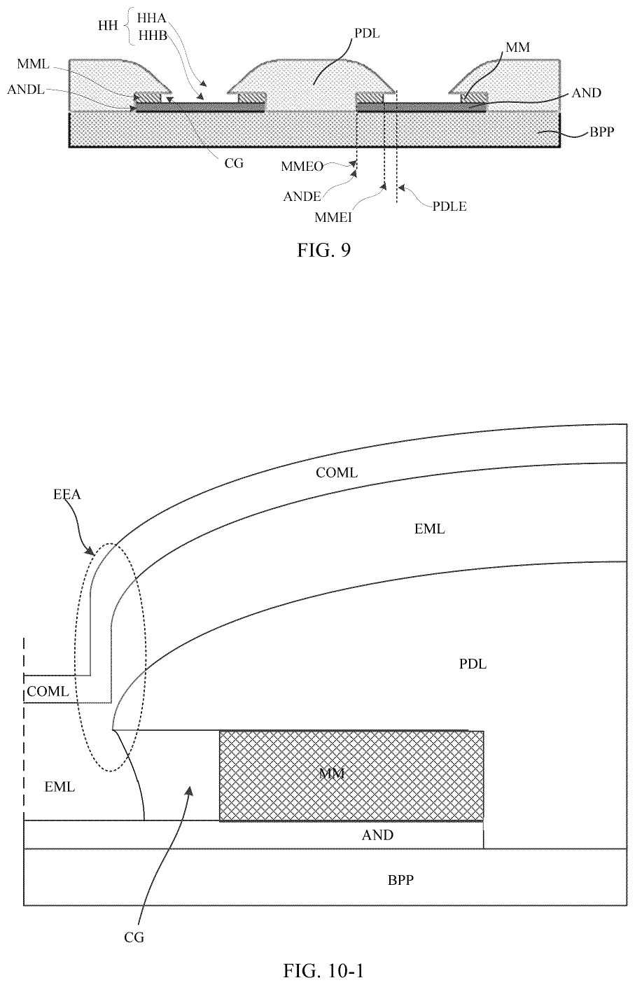

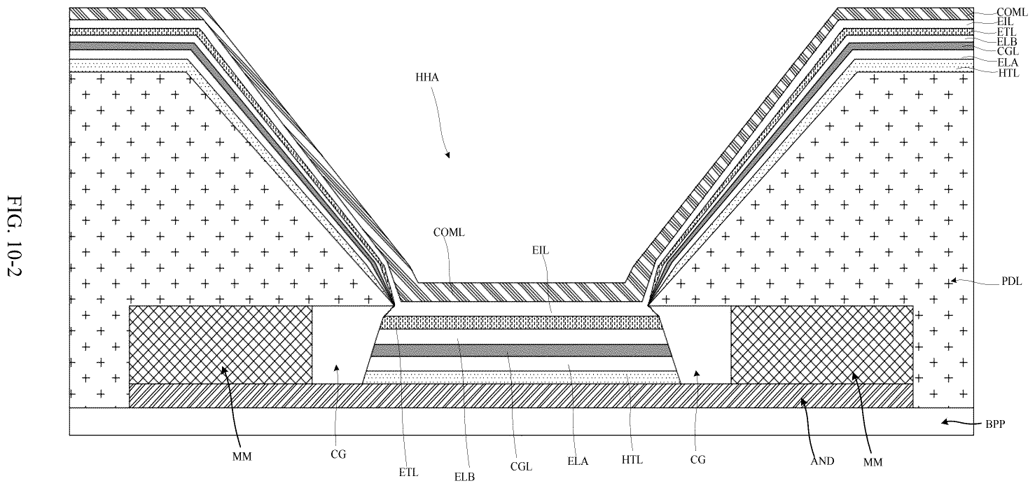

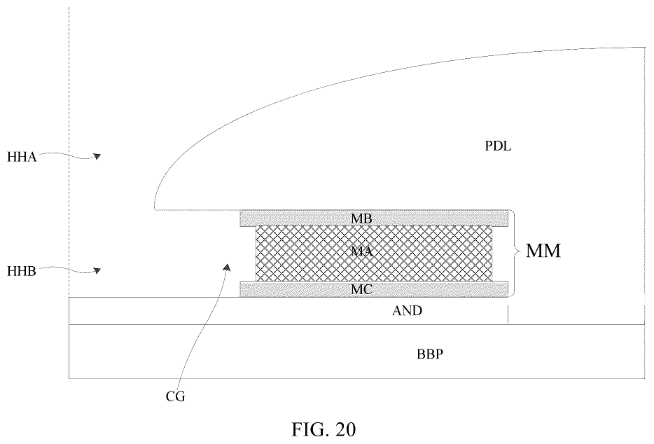

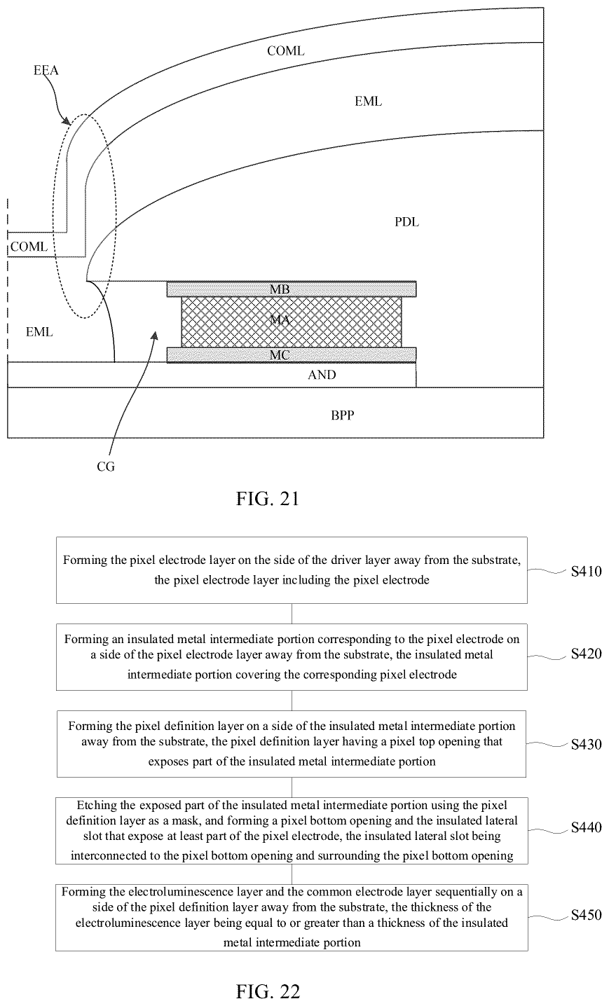

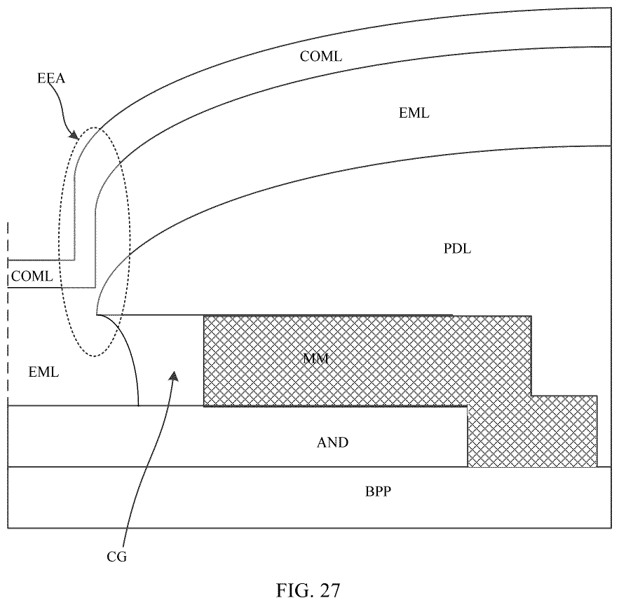

The present disclosure provides a display panel PNL and a method for preparing the display panel PNL. Referring to FIG. 1, the display panel PNL includes a substrate BP, a driver layer F100 and a pixel layer F200 stacked in sequence. The pixel layer F200 includes a pixel electrode layer ANDL, an insulated metal layer MML (not shown in FIG. 1, see FIG. 10-1), a pixel definition layer PDL, an electroluminescence layer EML and a common electrode layer COML stacked in sequence on a side of the driver layer F100 away from the substrate BP. Referring to FIG. 9, FIG. 10-1, FIG. 20, FIG. 21, FIG. 26, and FIG. 27, the pixel electrode layer ANDL has pixel electrodes AND, and the insulated metal layer MML has insulated metal blocks MM in one-to-one correspondence with the pixel electrodes AND; the insulated metal block MM and the pixel definition layer PDL are provided with a pixel opening HH that exposes the corresponding pixel electrode AND; an insulated lateral slot CG that surrounds the pixel opening HH and opens at the pixel opening HH, is provided between the insulated metal block MM and the pixel opening HH; and the electroluminescence layer EML covers the pixel opening HH, and a thickness of the electroluminescence layer EML is equal to or greater than a thickness of the insulated metal block MM.

In the display panel PNL of the present disclosure, the insulated lateral slot CG is provided between the pixel definition layer PDL and the pixel electrode AND. Therefore, multiple film layers of the EML layer will be staggered at the insulated lateral slot CG and the continuity cannot be maintained. In this way, the lateral current leakage of Organic Light-Emitting Diode (OLED) will be reduced or eliminated, which can avoid the crosstalk of color caused by the lateral current leakage of OLED on the one hand, and avoid the electroluminescence layer EML from emitting light outside the light-emitting definition area on the other hand, thereby ensuring the accuracy of the luminous brightness and luminous area of OLED, and further avoiding the color shift caused by inaccurate emitting light. In the embodiments of the present disclosure, referring to FIG. 9, the pixel opening HH includes a pixel top opening HHA formed by the pixel definition layer PDL and a pixel bottom opening HHB formed by the insulated metal block MM; and the thickness of the electroluminescence layer EML is not less than the insulated metal block MM. This prevents the electroluminescence layer EML of the OLED from completely falling into the pixel bottom opening HHB, thus reducing the impact of the insulated lateral slot CG on the common electrode layer COML and ensuring the electrical continuity of common electrode layer COML.

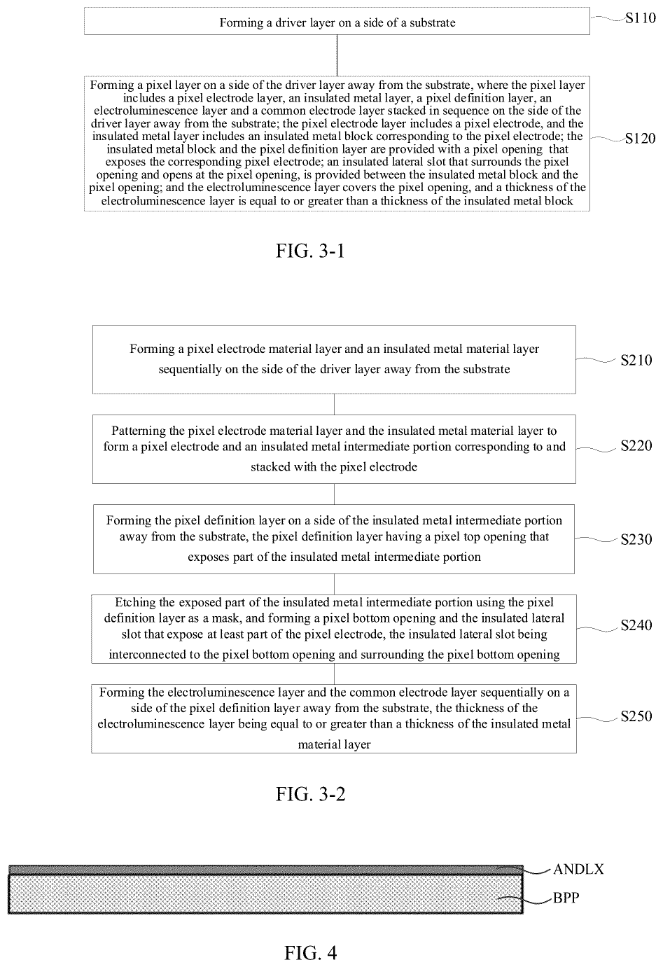

Accordingly, referring to FIG. 3-1, the display panel PNL of the present disclosure can be prepared using a method shown in the following steps S110 and S120.

Step S110, forming a driver layer F100 on a side of a substrate BP.

Step S120, forming a pixel layer F200 on a side of the driver layer F100 away from the substrate BP. The pixel layer F200 includes a pixel electrode layer ANDL, an insulated metal layer MML, a pixel definition layer PDL, an electroluminescence layer EML and a common electrode layer COML stacked in sequence on the side of the driver layer F100 away from the substrate BP. The pixel electrode layer ANDL includes a pixel electrode AND, and the insulated metal layer MML includes an insulated metal block MM corresponding to the pixel electrode AND; the insulated metal block MM and the pixel definition layer PDL are provided with a pixel opening HH that exposes the corresponding pixel electrode AND; an insulated lateral slot CG that surrounds the pixel opening HH and opens at the pixel opening HH, is provided between the insulated metal block MM and the pixel opening HH; and the electroluminescence layer EML covers the pixel opening HH, and a thickness of the electroluminescence layer EML is equal to or greater than a thickness of the insulated metal block MM.

In some embodiments of the present disclosure, the substrate BP may be a substrate BP of an inorganic material or a substrate BP of an organic material. For example, in one embodiment of the present disclosure, the material of the substrate BP may be a glass material such as soda lime glass, quartz glass, sapphire glass, or a metal material such as stainless steel, aluminum, nickel, etc. In another embodiment of the present disclosure, the material of the substrate BP may be polymethyl methacrylate, polyvinyl alcohol, polyvinyl phenol, polyether sulfone, polyimide, polyamide, polyacetal, polycarbonate, polyethylene terephthalate, polyethylene naphthalate, or a combination thereof. In another embodiment of the present disclosure, the substrate BP may also be a flexible substrate BP, for example, the material of the substrate BP may be polyimide. The substrate BP may also be a composite of multiple layers of materials, for example, in one embodiment of the present disclosure, the substrate BP may include a base film layer, a pressure-sensitive adhesive layer, a first polyimide layer, and a second polyimide layer stacked in sequence.

The driver layer F100 is provided with pixel driver circuits for driving sub-pixels. In the driver layer F100, any of the pixel driving circuits may include a transistor F100M and a storage capacitor. Further, the transistor F100M may be a thin film transistor, which may be selected from a top-gate thin film transistor, a bottom-gate thin film transistor, or a dual-gate thin film transistor; the material of the active layer of the thin film transistor may be an amorphous silicon semiconductor material, a low-temperature polycrystalline silicon semiconductor material, a metal oxide semiconductor material, an organic semiconductor material, or another type of semiconductor material; and the thin film transistor may be an N-type thin film transistor or P-type thin film transistor.

It should be understood that any two of the transistors in the pixel driver circuit may or may not be of the same type as each other. Exemplarily, in one embodiment, in a pixel driver circuit, some of the transistors may be N-type transistors and some of the transistors may be P-type transistors. Further exemplarily, in another embodiment of the present disclosure, in a pixel driver circuit, the material of the active layer of some of the transistors may be a low-temperature polycrystalline silicon semiconductor material and the material of the active layer of some of the transistors may be a metal oxide semiconductor material. In some embodiments of the present disclosure, the thin film transistors are low-temperature polycrystalline silicon transistors. In some other embodiments of the present disclosure, some of the thin film transistors are low-temperature polycrystalline silicon transistors and some of the thin film transistors are metal oxide transistors.

Optionally, the driver layer F100 may include a semiconductor layer SEMI, a gate insulating layer GI, a gate layer GT, an interlayer dielectric layer ILD, and a source and drain metal layer SD, etc., that are stacked between the substrate BP and the pixel layer F200. Each thin film transistor and storage capacitor can be formed by the film layers of semiconductor layer SEMI, gate insulating layer GI, gate layer GT, interlayer dielectric layer ILD, and source and drain metal layer SD. The position relationships of the film layers may be determined according to the film layer structure of the thin film transistor. Further, the semiconductor layer SEMI can be used to form the channel region of the transistor; the gate layer can be used to form the gate layer lines such as a scan line, a reset control line, a light-emitting control line, etc., or can be used to form the gate of the transistor, or part or all of electrode plates of the storage capacitor; and the source and drain metal layer can be used to form the source and drain metal layer lines such as a data voltage line, a driver voltage line, etc., or part or all of electrode plates of the storage capacitor.

In one example, referring to FIG. 1, the driver layer F100 may include a semiconductor layer SEMI, a gate insulating layer GI, a gate layer GT, an interlayer dielectric layer ILD, and a source and drain metal layer SD stacked in sequence, so that the resulting thin film transistor is a top-gate type thin film transistor.

In another example, the driver layer F100 may include a gate layer GT, a gate insulating layer GI, a semiconductor layer SEMI, an interlayer dielectric layer ILD, and a source and drain metal layer SD stacked in sequence, so that the resulting thin film transistor is a bottom-gate type thin film transistor.

In the display panel PNL of the present disclosure, the gate layer may be one layer, or include two or three layers as desired. In one example, the gate layer GT may include a first gate layer and a second gate layer, and the gate insulating layer GI may include a first gate insulating layer for isolating the semiconductor layer SEMI from the first gate layer, and a second gate insulating layer for isolating the first gate layer from the second gate layer. For example, the driver layer F100 may include a semiconductor layer SEMI, a first gate insulating layer, a first gate layer, a second gate insulating layer, a second gate layer, an interlayer dielectric layer ILD, and a source and drain metal layer SD, stacked sequentially on one side of the substrate BP. In one example, the gate layer GT may include a first gate layer and a second gate layer, and the semiconductor layer SEMI may be disposed between the first gate layer and the second gate layer; and the gate insulating layer GI may include a first gate insulating layer for isolating the semiconductor layer SEMI from the first gate layer, and a second gate insulating layer for isolating the second gate layer from the semiconductor layer SEMI. For example, the driver layer F100 may include a first gate layer, a first gate insulating layer, a semiconductor layer SEMI, a second gate insulating layer, a second gate layer, an interlayer dielectric layer ILD, and a source and drain metal layer SD, stacked sequentially on one side of the substrate BP. In these ways, a transistor having a dual-gate structure can be formed. In one example, the semiconductor layer SEMI may include a low-temperature polycrystalline silicon semiconductor layer and a metal oxide semiconductor layer, the gate layer includes a first gate layer and a second gate layer, and the gate insulating layer includes a first to third gate insulating layer. The driver layer F100 may include a low temperature polysilicon semiconductor layer, a first gate insulating layer, a first gate layer, a second gate insulating layer, a metal oxide semiconductor layer, a third gate insulating layer, a second gate layer, an interlayer dielectric layer ILD, and a source and drain metal layer SD, stacked sequentially on one side of the substrate BP. In one example, the semiconductor layer SEMI may include a low-temperature polysilicon semiconductor layer and a metal oxide semiconductor layer, the gate layer includes first to third gate layers, and the gate insulating layer includes first to third gate insulating layers. The driver layer F100 may include a low-temperature polysilicon semiconductor layer, a first gate insulating layer, a first gate layer, an insulating buffer layer, a second gate layer, a second gate insulating layer, a metal oxide semiconductor layer, a third gate insulating layer, a third gate layer, an interlayer dielectric layer ILD, and a source and drain metal layer SD, stacked sequentially on one side of the substrate BP.

In the display panel PNL of the present disclosure, the source and drain metal layer may be one layer, or include two or three layers as desired. In one example, the source and drain metal layer may include a first source and drain metal layer and a second source and drain metal layer stacked sequentially on one side of the interlayer dielectric layer ILD away from the substrate, and an insulating layer, such as a passivation layer and/or a flattening layer, may be disposed between the first source and drain metal layer and the second source and drain metal layer. In another example, the source and drain metal layer may include a first source and drain metal layer, a second source and drain metal layer, and a third source and drain metal layer stacked sequentially on one side of the interlayer dielectric layer ILD away from the substrate; an insulating layer, such as a passivation layer and/or a resin layer, may be disposed between the first source and drain metal layer and the second source and drain metal layer; and an insulating layer, such as a passivation layer and/or a flattening layer, may be disposed between the second source and drain metal layer and the third source and drain metal layer.

Optionally, the driver layer F100 may also include a passivation layer, which may be disposed on the surface of the source and drain metal layer SD away from the substrate BP to protect the source and drain metal layer SD.

Optionally, the driver layer F100 may also include an inorganic buffer layer Buff disposed between the substrate BP and the semiconductor layer SEMI, and the semiconductor layer SEMI, the gate layer GT, etc. are located on one side of the buffer material layer away from the substrate BP. The material of the buffer material layer can be silicon oxide, silicon nitride and other inorganic insulating materials. The buffer material layer can be a single layer of inorganic material or include multiple layers of inorganic material.

Optionally, the driver layer F100 may also include a flattening layer PLN disposed between the source and drain metal layer SD and the pixel layer F200, and the flattening layer PLN can provide a flattening surface for the pixel electrode AND. Optionally, the material of the flattening layer PLN may be an organic material.

In the present disclosure, the base consisting of the substrate BP and the driver layer F100 together can be defined as the driver substrate BPP, and the pixel layer F200 can be formed on the driver substrate BPP.

In the embodiments of the present disclosure, the pixel layer F200 may be provided on one side of the driver layer F100 away from the substrate BP (i.e., provided on the driver substrate BPP), which may include film layers such as a pixel electrode layer ANDL, an insulated metal layer MML, a pixel definition layer PDL, an electroluminescence layer EML, and a common electrode layer COML stacked in sequence. The pixel electrode layer ANDL has one or more pixel electrodes AND, such as a plurality of pixel electrodes AND arranged in an array. The insulated metal layer MML has insulated metal blocks MM in one-to-one correspondence with the plurality of pixel electrodes AND, and the insulated metal block MM and the pixel definition layer PDL are provided with a pixel opening HH exposing the corresponding pixel electrode AND correspondingly. The electroluminescence layer EML covers the pixel opening HH and the common electrode layer COML covers the surface of the electroluminescence layer EML away from the pixel electrode AND. In this way, the area where the pixel electrode AND is exposed by the pixel definition layer PDL is the light-emitting definition area, the electroluminescence layer EML and the common electrode layer COML can cover the light-emitting definition area in turn, and the electroluminescence layer EML emits light in the light-emitting definition area.

In one embodiment of the present disclosure, the pixel layer F200 may also include a support pillar layer, the support pillar layer being provided on one side of the pixel definition layer PDL away from the substrate BP and having a plurality of support pillars. The support pillar PS can support the fine metal mask plate during the vapor deposition process.

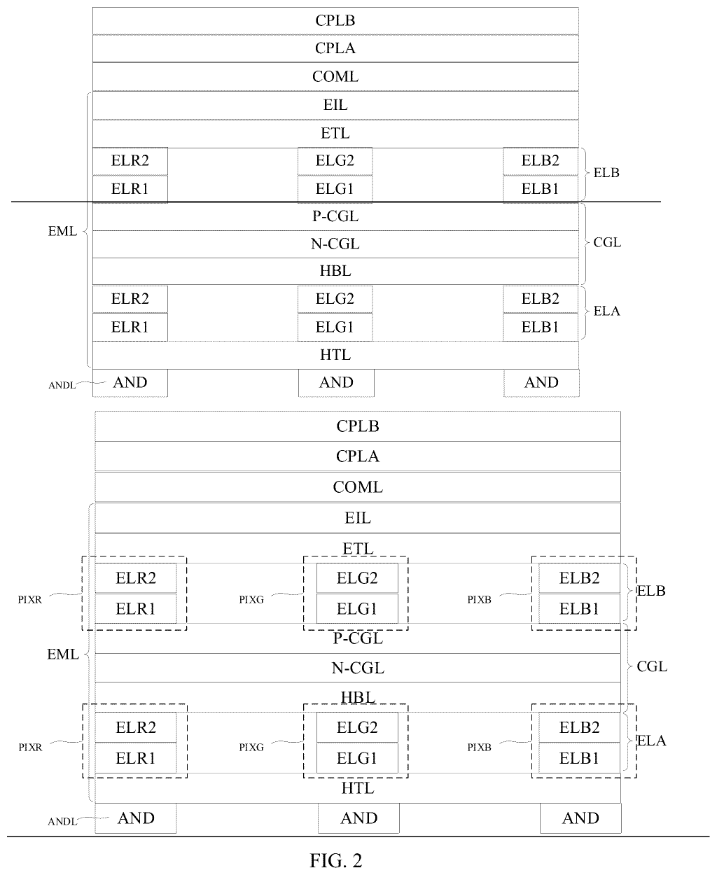

The electroluminescence layer EML may include an electroluminescence layer, and may include one or more of the following layers: a hole injection layer, a hole transport layer, an electron blocking layer, a hole blocking layer, an electron transport layer, and an electron injection layer. Any one of these layers can be a single layer or include multiple layers. Each layer of the electroluminescence layer EML may be prepared by an evaporation process, and the pattern of the layer may be defined during evaporation using a fine metal mask plate or an open mask plate. In one example, some of the film layers of the electroluminescence layer EML may be prepared using an open mask plate. Referring to FIG. 2, some of the film layers (e.g., hole transport layer HTL, hole blocking layer HBL, electron transport layer ETL, electron injection layer EIL, etc.) can cover the light-emitting definition areas of multiple OLEDs. In the embodiments of the present disclosure, by providing the insulated lateral slot CG, these film layers can be staggered at the edge of the pixel definition layer PDL (i.e., at the edge PDLE), which in turn makes the effective transfer of charge between these film layers in different light-emitting definition areas difficult, thus avoiding color crosstalk.

In one embodiment of the present disclosure, the OLED is a tandem organic electroluminescence diode (Tandem OLED) including a plurality of organic light-emitting layers EL connected in series by one or more charge generation layers CGL, for example, including a first organic light-emitting layer ELA and a second organic light-emitting layer ELB connected in series by a charge generation layer CGL. In this way, the luminous efficiency of the OLED can be improved, the driving voltage and power consumption can be reduced, and the lifetime and stability of the OLED can be prolonged. For example, in the example shown in FIG. 2, the electroluminescenc layer EML of the OLED includes the first organic light-emitting layer ELA, the charge generation layer CGL, and the second organic light-emitting layer ELB, which are stacked in sequence between the pixel electrodes AND and the common electrode layer COML. Since the charge generation layer CGL usually has a large conductivity, it causes the OLED to have significant lateral current leakage and luminescence outside the defined area, which may reduce the display quality of the display panel PNL. In the present disclosure, by providing the insulated metal block(s) MM between the pixel definition layer PDL and the pixel electrode(s) AND, and forming the insulated lateral slot(s) CG by making the insulated metal block(s) MM shrink inward, the pixel definition layer PDL is overhung at the lower edge of the pixel top opening HHA (close to the edge of the opening of the substrate BP, i.e., the edge PDLE), so that the charge generation layer CGL and other film layers are mislaminated when deposited at the lower edge of the pixel top opening HHA, which results in a discontinuity of the charge generation layer CGL, i.e., the portion of the charge generation layer CGL inside the top pixel opening HHA is not continuous with the portion of the charge generation layer CGL overlaying the pixel definition layer PDL.

In one embodiment of the present disclosure, referring to FIG. 2, the sub-pixels PIX on the display panel PNL include a red sub-pixel PIXR, a blue sub-pixel PIXB, and a green sub-pixel PIXG. The red sub-pixel PIXR, the blue sub-pixel PIXB, and the green sub-pixel PIXG may share the same hole transport layer HTL, charge generation layer CGL, electron transport layer ETL, electron injection layer EIL, etc. That is, the hole transport layer HTL, the charge generation layer CGL, the electron transport layer ETL, and the electron injection layer EIL can be prepared by vapor deposition using open masks. The organic light-emitting layer EL of any sub-pixel PIX includes a first organic light-emitting layer ELA and a second organic light-emitting layer ELB, and a charge generation layer CGL is provided between the first organic light-emitting layer ELA and the second organic light-emitting layer ELB. Further, the first organic light-emitting layer ELA or the second organic light-emitting layer ELB includes one or more layers of materials to adjust the energy level coordination, carrier transport efficiency coordination or constraint on exciton generation and diffusion between different film layers. Exemplarily, the first organic light-emitting layer ELA and the second organic light-emitting layer ELB of the red sub-pixel PIXR each includes a first red organic light-emitting layer ELR1 and a second red organic light-emitting layer ELR2 stacked in sequence; the first organic light-emitting layer ELA and the second organic light-emitting layer ELB of the blue sub-pixel PIXB each includes a first blue organic light-emitting layer ELB1 and a second blue organic light-emitting layer ELB2 stacked in sequence; and the first organic light-emitting layer ELA and the second organic light-emitting layer ELB of the green sub-pixel PIXG each includes a first green organic light-emitting layer ELG1 and a second green organic light-emitting layer ELG2 stacked in sequence.

In one embodiment of the present disclosure, referring to FIG. 2, the charge generation layer CGL may include a hole blocking layer HBL, an N-type charge generation layer N-CGL, and a P-type charge generation layer P-CGL stacked in sequence to provide electrons to the first organic light-emitting layer ELA and holes to the second organic light-emitting layer ELB, and to constrain exciton diffusion in the first organic light-emitting layer ELA.

In one embodiment of the present disclosure, the pixel layer F200 further includes a first light extraction layer CPLA and a second light extraction layer CPLB located on one side of the common electrode layer COML away from the substrate BP, and the first light extraction layer CPLA and the second light extraction layer CPLB can improve the light extraction efficiency of the OLED through the cooperation of refractive index (e.g., high refractive index).

In one example, the material of the electron transport layer ETL may be a mixture of 8-Hydroxyquinolinolato-lithium and a hole blocking material.

In one example, the material of the electron injection layer EIL can be ytterbium (Yb).

In one example, the material of the second light extraction layer CPLB is lithium fluoride.

In one example, the material of the P-type charge generation layer, P-CGL, may include a mixture of a hole transport material and a hole injection material.

In one example, the material of the N-type charge generation layer, N-CGL, may include a mixture of an electron transport material and a hole injection material.

In one embodiment of the present disclosure, the material of the pixel electrode AND may include a reflective layer and a conductive metal oxide layer stacked sequentially on the side of the driver layer F100 away from the substrate BP. Further, each of two sides of the reflective electrode layer may be provided with a conductive metal oxide layer. For example, the pixel electrode AND includes an indium tin oxide (ITO) layer, a silver reflective layer, and an ITO layer, stacked sequentially.

Optionally, the display panel may also include a thin film encapsulation layer TFE, which is disposed on the surface of the pixel layer F200 away from the substrate BP, and may include alternating layers of inorganic and organic encapsulation layers. A touch layer is provided on one side of the thin film encapsulation layer TFE away from the substrate BP. The inorganic encapsulation layer can effectively block external moisture and oxygen, to avoid material degradation caused by the invasion of water and oxygen into the electroluminescence layer EML. Optionally, the edge of the inorganic encapsulation layer may be located in the periphery. The organic encapsulation layer is located between two adjacent inorganic encapsulation layers in order to achieve flattening and weakening of the stress between the inorganic encapsulation layers. The edge of the organic encapsulation layer may be located between the edge of the display area and the edge of the inorganic encapsulation layer. For example, the thin film encapsulation layer TFE includes the first inorganic encapsulation layer CVDA, the organic encapsulation layer INJ, and the second inorganic encapsulation layer CVDB stacked in sequence on the side of the pixel layer F200 away from the substrate BP.

Optionally, the display panel PNL may also include a touch functional layer TSL, which is provided on the side of the thin film encapsulation layer TFE away from the substrate BP to enable touch operation of the display panel.

Optionally, the display panel PNL may also include an anti-reflective layer CFL, and the anti-reflective layer CFL may be provided on the side of the thin film encapsulation layer TFE away from the pixel layer F200 for reducing the reflection of ambient light from the display panel, thereby reducing the effect of ambient light on the display.

In one embodiment of the present disclosure, the pixel layer F200 can be formed on the side of the driver layer F100 away from the substrate BP using the method shown in FIG. 3-2.

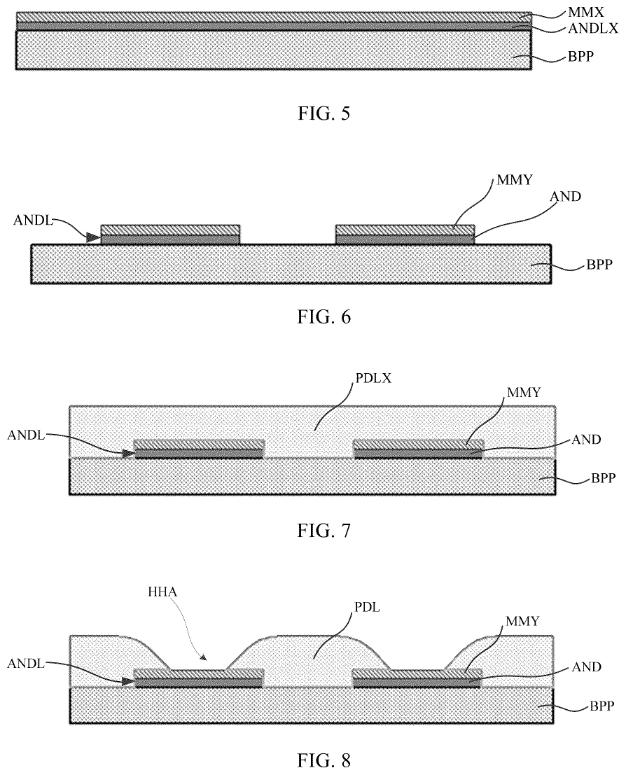

Step S210, referring to FIGS. 4 and 5, forming a pixel electrode material layer ANDLX (eventually patterned as the pixel electrode layer ANDL) and an insulated metal material layer MMX (eventually patterned as the insulated metal layer MML) sequentially on the side of the driver layer F100 away from the substrate BP. In this embodiment, the material of the insulated metal material MMX may be an elementary metal or a metal alloy, i.e., it is a single layer of metal material. For example, it can be an elementary material such as copper, molybdenum, aluminum, etc., or it can be a copper alloy or aluminum alloy. Of course, in other examples of the present disclosure, the material of the insulated metal material layer MMX may be multiple layers of metal material that can be etched substantially simultaneously, or may be other inorganic materials that can be wet etched, as long as the insulated metal material layer MMX can be wet etched and has a larger etch selectivity ratio than the pixel electrode AND and pixel definition layer PDL.

In one example, the thickness of the insulated metal layer MMX can range from 100 to 1000 Å. Accordingly, in the formed display panel PNL, the thickness of the insulated metal block MM ranges from 100 to 1000 Å.

Step S220, referring to FIG. 6, patterning the pixel electrode material layer ANDLX and the insulated metal material layer MMX to form a pixel electrode AND and an insulated metal intermediate portion MMY corresponding to and stacked with the pixel electrode AND. In this step, the pixel electrode material layer ANDLX and the insulated metal material layer MMX can be etched simultaneously, which reduces the number of mask plates and the patterning processes required to pattern the pixel electrode material layer ANDLX and the insulated metal material layer MMX. The pixel electrode material layer ANDLX forms a plurality of pixel electrodes AND after patterning, and the insulated metal material layer MMX forms a plurality insulated metal intermediate portions MMY in one-to-one correspondence with the plurality of pixel electrodes AND after patterning. In this example, the ITO of the pixel electrode material layer ANDLX may not have been heat treated and therefore has a low degree of crystallization and can be etched using milder etching conditions.

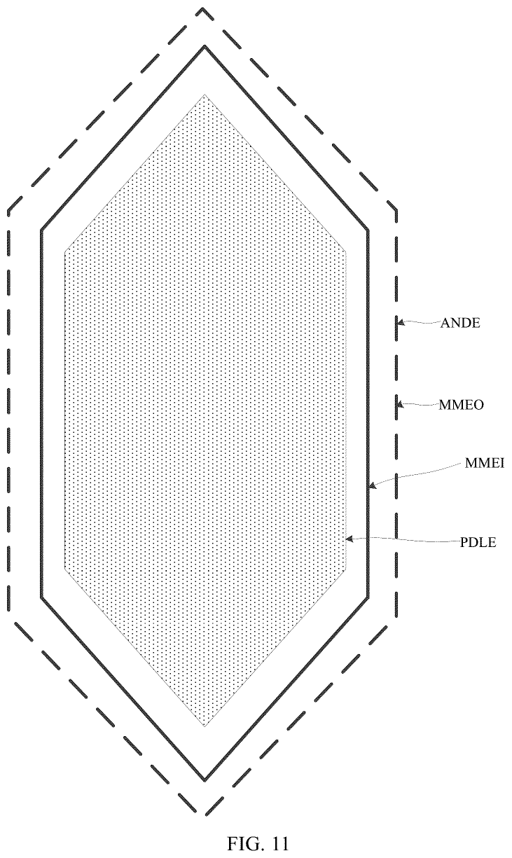

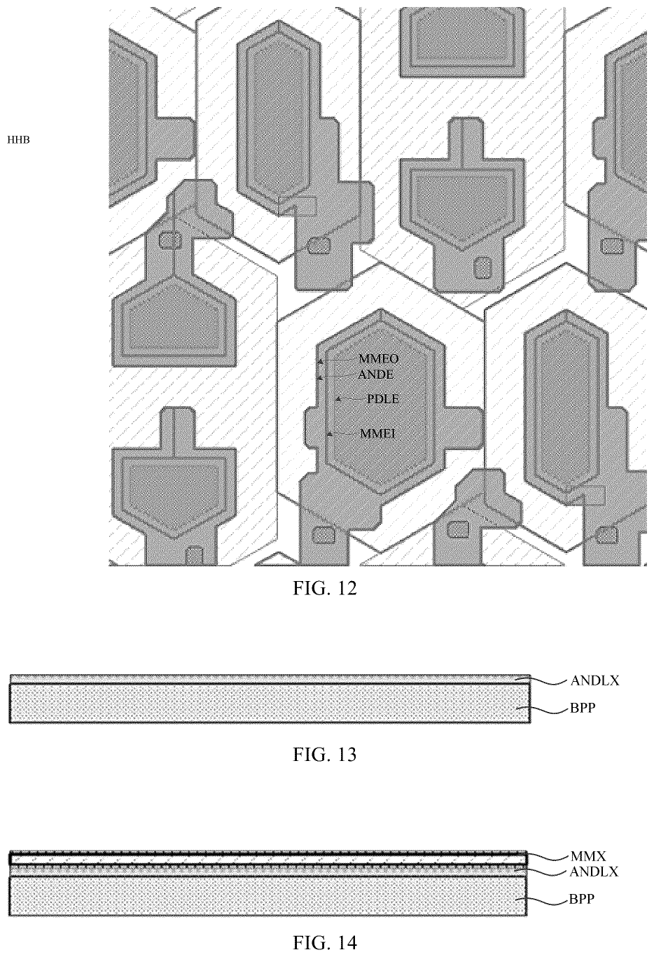

In one example, referring to FIG. 6, the orthographic projection of the insulated metal intermediate portion MMY on the driver substrate BPP overlaps with the orthographic projection of the corresponding pixel electrode AND on the driver substrate BPP. That is, the outer edge of the insulated metal intermediate portion MMY (i.e., the edge MMEO in FIG. 11 and FIG. 12) and the outer edge of the corresponding pixel electrode AND (i.e., the edge ANDE in FIG. 11) are substantially flush.

Step S230, referring to FIG. 7 and FIG. 8, forming the pixel definition layer PDL on a side of the insulated metal intermediate portion MMY away from the substrate BP, the pixel definition layer PDL having a pixel top opening HHA that exposes part of the insulated metal intermediate portion MMY. Specifically, a pixel definition material layer PDLX covering the pixel electrode AND and the insulated metal intermediate portion MMY may be formed first, and then the pixel definition material layer PDLX may be patterned to form the pixel definition layer PDL with the pixel top opening HHA.

Referring to FIG. 8, each pixel top opening HHA corresponds to each pixel electrode AND and also to each insulated metal intermediate portion MMY. The pixel top opening HHA exposes part of the corresponding insulated metal intermediate portion MMY. In this case, the lower edge of the pixel top opening HHA (the edge of the opening close to the substrate BP, represented by the edge PDLE in FIG. 11) is the edge of the pixel definition layer PDL at the pixel top opening HHA, which defines the light-emitting definition area of the electroluminescence layer EML. Referring to FIG. 8, part of the insulated metal intermediate portion MMY is exposed by the pixel top opening HHA and part of the insulated metal intermediate portion MMY is covered by the pixel definition layer PDL and the part of the insulated metal intermediate portion MMY covered by the pixel definition layer PDL is in an annular shape.

Optionally, the various insulated metal intermediate portions MMY are discontinuous with each other to avoid short-circuiting between the pixel electrodes AND corresponding to the different insulated metal intermediate portions MMY. Accordingly, the insulated metal blocks MM corresponding to the various pixel electrodes AND one by one are set insulated from each other to avoid short-circuiting between the pixel electrodes AND corresponding to different insulated metal blocks MM through the insulated metal blocks MM.

Step S240, referring to FIG. 9, etching the exposed part of the insulated metal intermediate portion MMY using the pixel definition layer PDL as a mask, and forming a pixel bottom opening HHB and the insulated lateral slot CG that expose at least part of the pixel electrode AND, the insulated lateral slot CG being interconnected to the pixel bottom opening HHB and surrounding the pixel bottom opening HHB. Thus, the insulated metal intermediate portion MMY is etched to form the insulated metal block MM. The pixel bottom opening HHB and the pixel top opening HHA together form the pixel opening H, and thus, the insulated metal block MM and the pixel definition layer PDL form the pixel opening HH exposing the pixel electrode AND, and the insulated metal block MM also forms the insulated lateral slot CG surrounding the pixel opening HH.

Referring to FIG. 9, the part of the insulated metal intermediate portion MMY exposed by the pixel top opening HHA is completely etched. In addition, the part of the insulated metal intermediate portion MMY covered by the pixel definition layer PDL is also partially etched, causing the insulated metal intermediate portion MMY to shrink inward, and the space formed after the shrinkage is the insulated lateral slot CG, and the remaining insulated metal intermediate portion MMY after etching is the insulated metal block MM corresponding to the pixel electrode AND. Referring to FIG. 9 and FIG. 11, there is a space between the inner edge (represented by the edge MMEI in FIG. 9) of the insulated metal block MM and the edge (represented by the edge PDLE in FIG. 9) of the pixel definition layer PDL at the pixel top opening HHA. In FIG. 9, the outer edge of the insulated metal block is represented by edge MMEO. Referring to FIG. 9, the insulated metal block is in a closed annular structure (the part between edge MMEI and edge MMEO), and the orthographic projection on the substrate of the pixel opening corresponding to the pixel electrode (the area surrounded by edge PDLE) is located in the orthographic projection (area surrounded by the edge MMEI) on the substrate of the inner cavity of the insulated metal block corresponding to the pixel electrode.

In one example, the insulated metal intermediate portion MMY may be wet etched and continued to be etched after the insulated metal intermediate portion MMY exposes the pixel electrode AND to cause the remaining insulated metal intermediate portion MMY to shrink to within the coverage of the pixel definition layer PDL to form the insulated lateral slot CG. Thus, the pixel definition layer PDL is overhung above the insulated lateral slot CG.

In one example, before etching the insulated metal intermediate portion MMY, the method for preparing the display panel PNL may also include performing a heat treatment on the pixel electrode AND. For example, the driver substrate BPP with the pixel electrode AND can be treated by an OVEN process, so that the ITO of the pixel electrode AND can be crystallized and the etch resistance of the ITO can be improved. The surface of the pixel electrode AND is not damaged by the etching solution during the wet etching of the insulated metal intermediate portion MMY, thus ensuring the luminous performance of the OLED.

In one example, the heat treatment of the pixel electrode AND may be carried out at 150˜200° C. and the time of heat treatment may be 0.5˜1.5 h.

In one example, the heat treatment of the pixel electrode AND may be performed after the formation of the pixel definition layer PDL and before the patterning of the insulated metal intermediate portion MMY.

Step S250, referring to FIG. 10-1 and FIG. 10-2, forming the electroluminescence layer EML and the common electrode layer COML sequentially on a side of the pixel definition layer PDL away from the substrate BP, the thickness of the electroluminescence layer EML being equal to or greater than a thickness of the insulated metal material layer MMX. Referring to FIG. 10-2, when the electroluminescence layer EML is deposited in the pixel bottom opening HHB, part of the material of the electroluminescence layer EML is deposited into the insulated lateral slot CG and the pixel definition layer PDL is overhanging above the insulated lateral slot CG, which causes at least part of the material layers of the electroluminescence layer EML to break off at the inner edge of the pixel definition layer PDL (i.e., the edge represented by the edge PDLE in FIG. 11, which is the edge of the lower opening of the top opening HHA, i.e., the edge of the pixel opening HH close to the substrate BP). That is, at least part of the film layers of the electroluminescence layer EML is broken at the area EEA in FIG. 10-2. In this way, crosstalk and light emission beyond the light-emitting definition area due to lateral current leakage between different OLEDs can be reduced.

Optionally, referring to FIG. 10-2, the thickness of the electroluminescence layer EML is greater than the thickness of the insulated lateral slot CG, which prevents the common electrode layer COML from sinking into the pixel bottom opening HHB, thus avoiding the breakage of the common electrode layer COML and ensuring the electrical continuity of the common electrode layer COML.

In another embodiment of the present disclosure, the methods shown in steps S310 to step 350 may be used to prepare the display panel PNL. The principles of the methods used in steps S310 to step 350 are substantially similar to the preparation methods described above, with the main difference being that the material of the insulated metal material layer MMX is a multilayer metal layer.

Step S310, referring to FIGS. 13 to 15, forming a pixel electrode material layer ANDLX and an insulated metal material layer MMX sequentially on the side of the driver layer F100 away from the substrate BP. In this embodiment, the insulated metal material layer MMX may include multiple layers of metal material, and each layer of metal material may be an elementary metal or an alloy.

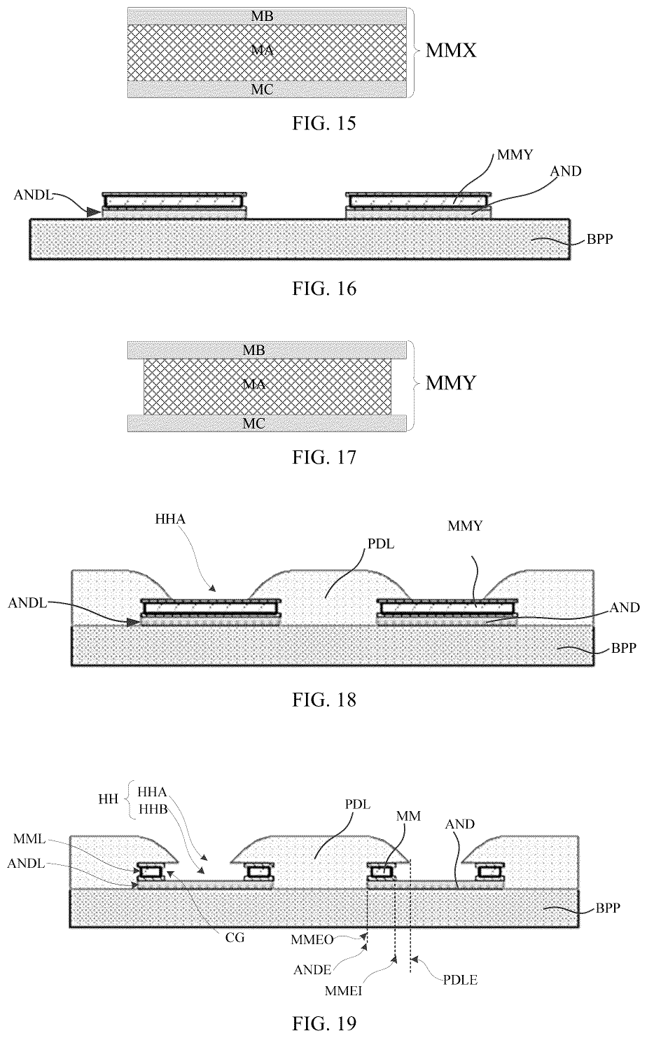

For example, the insulated metal material layer MMX includes a first metal layer MA and a second metal layer MB stacked sequentially on the side of the pixel electrode AND away from the substrate BP, the second metal layer MB having a weaker metal activity than the first metal layer MA (e.g., the etching rate of the second metal layer MB is less than the etching rate of the first metal layer MA during etching). In this way, when patterning the insulated metal material layer MMX by etching to form the insulated metal intermediate portion MMY, the second metal layer MB protrudes from the first metal layer MA at the edge of the insulated metal intermediate portion MMY, i.e., the second metal layer MB is overhung. This overhang facilitates the strengthening and enlargement of the insulated lateral slot CG and thus more facilitates the break-up of the electroluminescence layer EML at the inner edge of the pixel definition layer PDL (i.e., the edge of the lower opening of the pixel opening HH). Further, referring to FIG. 15, the insulated metal material layer MMX may further include a third metal layer MC located on the side of the first metal layer MA close to the substrate BP, and the metal activity of the third metal layer MC may also be weaker than that of the first metal layer MA (e.g., the etching rate of the third metal layer MC is less than that of the first metal layer MA during etching). In this way, the first metal layer MA is disposed between the second metal layer MB and the third metal layer MC. For example, the insulated metal material layer MMX may include a titanium layer, an aluminum layer, and a titanium layer stacked in sequence, or a copper-nickel alloy layer, a copper layer, and a copper-nickel alloy layer, etc., stacked in sequence. Accordingly, in the resulting display panel PNL, the insulated metal block MM includes the first metal layer MA and the second metal layer MB stacked sequentially on the side of the pixel electrode AND away from the substrate BP, the second metal layer MB has a weaker metal activity than the first metal layer MA, and the second metal layer MB protrudes from the first metal layer MA at the edge of the insulated metal block MM close to the insulated lateral slot CG.

In one example, the thickness of the insulated metal material layer MMX may range from 100 to 1000 Å. Accordingly, in the resulting display panel PNL, the thickness of the insulated metal block MM ranges from 100 to 1000 Å. In this way, it is possible to avoid the problem that the common electrode layer COML is partially or completely cut off due to a too thick insulated metal block MM, and that the insulated metal material layer MMX is too thin and prone to uneven thickness.

Step S320, referring to FIG. 16 and FIG. 17, patterning the pixel electrode material layer ANDLX and the insulated metal material layer MMX to form a pixel electrode AND and an insulated metal intermediate portion MMY corresponding to and stacked with the pixel electrode AND. In this step, the pixel electrode material layer ANDLX and the insulated metal material layer MMX can be etched simultaneously, which can reduce the number of mask plates and the patterning processes required to pattern the pixel electrode material layer ANDLX and the insulated metal material layer MMX. The pixel electrode material layer ANDLX forms a plurality of pixel electrodes AND after patterning, and the insulated metal material layer MMX forms a plurality insulated metal intermediate portions MMY. In this example, the ITO of the pixel electrode material layer ANDLX may not have been heat treated and therefore has a low degree of crystallization and can be etched using milder etching conditions.

In one example, referring to FIG. 16, the orthographic projection of the insulated metal intermediate portion MMY on the driver substrate BPP overlaps with the orthographic projection of the pixel electrode AND on the driver substrate BPP. That is, the outer edge of the insulated metal intermediate portion MMY (i.e., the edge MMEO in FIG. 11) and the outer edge of the pixel electrode AND (i.e., the edge ANDE in FIG. 19) are substantially flush.

In one example, referring to FIG. 17, the first metal layer MA of the insulated metal intermediate portion MMY is laterally etched, leaving the edges of the second metal layer MB and the third metal layer MC overhanging.

Step S330, referring to FIG. 18, forming the pixel definition layer PDL on a side of the insulated metal intermediate portion MMY away from the substrate BP, the pixel definition layer PDL having a pixel top opening HHA that exposes part of the insulated metal intermediate portion MMY. Specifically, a pixel definition material layer PDLX covering the pixel electrode AND and the insulated metal intermediate portion MMY may be formed first, and then the pixel definition material layer PDLX may be patterned to form the pixel definition layer PDL with the pixel top opening HHA.

Referring to FIG. 18, each pixel top opening HHA corresponds to each pixel electrode AND and also to each insulated metal intermediate portion MMY. The pixel top opening HHA exposes part of the corresponding insulated metal intermediate portion MMY. In this case, the lower edge of the pixel top opening HHA (the edge of the opening close to the substrate BP, represented by the edge PDLE in FIG. 19) is the edge of the pixel definition layer PDL at the pixel top opening HHA, which defines the light-emitting definition area of the electroluminescence layer EML. Referring to FIG. 19, part of the insulated metal intermediate portion MMY is exposed by the pixel top opening HHA and part of the insulated metal intermediate portion MMY is covered by the pixel definition layer PDL and the part of the insulated metal intermediate portion MMY covered by the pixel definition layer PDL is in an annular shape.

Step S340, referring to FIG. 19, etching the exposed part of the insulated metal intermediate portion MMY using the pixel definition layer PDL as a mask, and forming a pixel bottom opening HHB and the insulated lateral slot CG that expose at least part of the pixel electrode AND, the insulated lateral slot CG being interconnected to the pixel bottom opening HHB and surrounding the pixel bottom opening HHB. Thus, the insulated metal intermediate portion MMY is etched to form the insulated metal block MM, and each insulated metal block MM serves as at least part of the insulated metal layer MML. The pixel bottom opening HHB and the pixel top opening HHA together form the pixel opening H, and thus, the insulated metal block MM and the pixel definition layer PDL form the pixel opening HH that exposes at least part of the corresponding pixel electrode AND, and the insulated metal block MM also forms the insulated lateral slot CG surrounding the pixel opening HH.

Referring to FIG. 19, the part of the insulated metal intermediate portion MMY exposed by the pixel top opening HHA is completely etched. In addition, the part of the insulated metal intermediate portion MMY covered by the pixel definition layer PDL is also partially etched, causing the insulated metal intermediate portion MMY to shrink inward, and the space formed after the shrinkage is the insulated lateral slot CG. Referring to FIG. 19, there is a space between the inner edge (represented by the edge MMEI in FIG. 19) of the insulated metal block MM and the edge (represented by the edge PDLE in FIG. 19) of the pixel definition layer PDL at the pixel top opening HHA.

In one example, the insulated metal intermediate portion MMY may be wet etched and continued to be etched after the insulated metal intermediate portion MMY exposes the pixel electrode AND to cause the remaining insulated metal intermediate portion MMY to shrink to within the coverage of the pixel definition layer PDL to form the insulated lateral slot CG. Thus, the pixel definition layer PDL is overhung above the insulated lateral slot CG.

In one example, referring to FIG. 20, during wet etching of the insulated metal intermediate portion MMY, the first metal layer MA in the insulated metal intermediate portion MMY will be laterally etched, thus leaving the second metal layer MB overhanging, which can enlarge the insulated lateral slot CG to improve the mismatch effect on at least part of the film layers of the electroluminescence layer EML.

In one example, before etching the insulated metal intermediate portion MMY, the method for preparing the display panel PNL may also include performing a heat treatment on the pixel electrode AND. For example, the driver substrate BPP with the pixel electrode AND can be treated by an OVEN process, so that the ITO of the pixel electrode AND can be crystallized and the etch resistance of the ITO can be improved. The surface of the pixel electrode AND is not damaged by the etching solution during the wet etching of the insulated metal intermediate portion MMY, thus ensuring the luminous performance of the OLED.

In one example, the heat treatment of the pixel electrode AND may be carried out at 150˜200° C. and the time of heat treatment may be 0.5˜1.5 h.

In one example, the heat treatment of the pixel electrode AND may be performed after the formation of the pixel definition layer PDL and before the patterning of the insulated metal intermediate portion MMY.

Step S350, referring to FIG. 21, forming the electroluminescence layer EML and the common electrode layer COML sequentially on a side of the pixel definition layer PDL away from the substrate BP, the thickness of the electroluminescence layer EML being equal to or greater than a thickness of the insulated metal material layer MMX. Referring to FIG. 21, when the electroluminescence layer EML is deposited in the pixel bottom opening HHB, part of the material of the electroluminescence layer EML is deposited into the insulated lateral slot CG and the pixel definition layer PDL is overhanging above the insulated lateral slot CG, which causes at least part of the material layers of the electroluminescence layer EML to break off at the inner edge of the pixel definition layer PDL (i.e., the edge represented by the edge PDLE in FIG. 19, which is the edge of the lower opening of the top opening HHA, i.e., the edge of the pixel opening HH close to the substrate BP). That is, at least part of the film layers of the electroluminescence layer EML is broken at the area EEA in FIG. 21. In this way, crosstalk and light emission beyond the light-emitting definition area due to lateral current leakage between different OLEDs can be reduced.

Optionally, referring to FIG. 21, the thickness of the electroluminescence layer EML is greater than the thickness of the insulated lateral slot CG, which prevents the common electrode layer COML from sinking into the pixel bottom opening HHB, thus avoiding the breakage of the common electrode layer COML and ensuring the electrical continuity of the common electrode layer COML.

In one embodiment of the present disclosure, the pixel layer F200 can be formed on the side of the driver layer F100 away from the substrate BP using the method shown in FIG. 22.

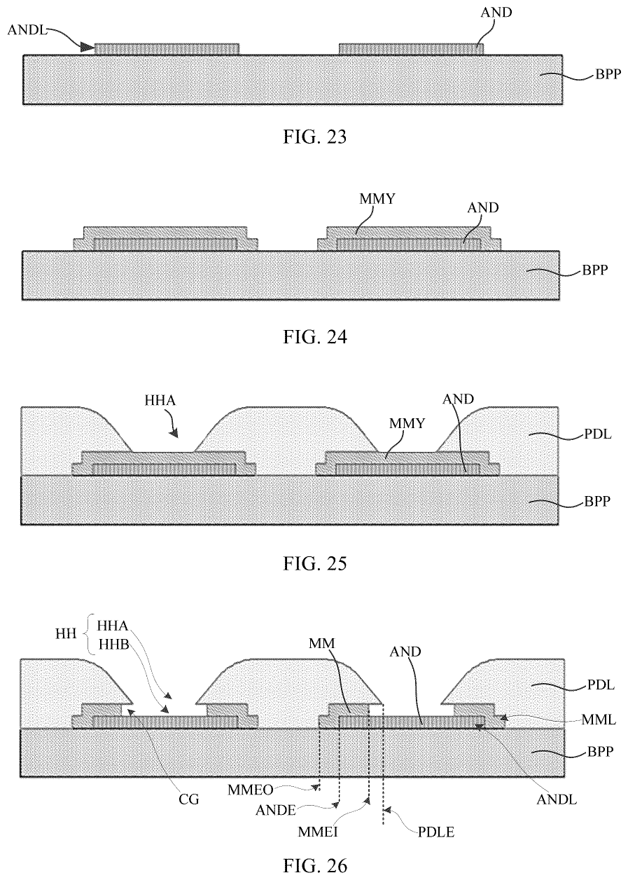

Step S410, referring to FIG. 23, forming the pixel electrode layer ANDL on the side of the driver layer F100 away from the substrate BP, the pixel electrode layer ANDL including the pixel electrode AND. For example, a pixel electrode material layer ANDLX can be formed on the side of the driver layer F100 away from the substrate BP, and then the pixel electrode material layer ANDLX can be patterned to form individual pixel electrodes AND. Compared with the method in which the insulated metal material layer MMX and the pixel electrode material layer ANDLX are etched simultaneously, the pixel electrode material layer ANDLX is etched separately here to reduce the difficulty of patterning the pixel electrode material layer ANDLX and to improve the precision and edge shape of the pixel electrode AND on the one hand. On the other hand, the interaction between different materials during simultaneous etching of the pixel electrode material layer ANDLX and the insulated metal material layer MMX can be avoided, for example, avoiding the formation of silver particles during the etching process, thus contributing to the improvement of the yield of the display panel PNL.

Step S420, referring to FIG. 24, forming an insulated metal intermediate portion MMY corresponding to the pixel electrode AND on a side of the pixel electrode layer ANDL away from the substrate BP, the insulated metal intermediate portion MMY covering the corresponding pixel electrode AND. For example, an insulated metal material layer MMX covering the pixel electrode layer ANDL can be formed first, and then the insulated metal material layer MMX can be patterned to form the insulated metal intermediate portion MMY corresponding to each pixel electrode AND. In this way, the pixel electrode material layer ANDLX and the insulated metal material layer MMX can be patterned separately, which can reduce the difficulty of the patterning operation and facilitates the improvement of the yield of the display panel PNL. In FIG. 26, the edge MMEO illustrates the outer edge of the insulated metal intermediate portion MMY and the final insulated metal block MM, and the edge ANDE illustrates the outer edge of the pixel electrode AND. Referring to the edges MMEO and ANDE in FIGS. 26 to 29, it can be seen that the insulated metal intermediate portion MMY covers the corresponding pixel electrode AND, and the orthographic projection of the pixel electrode AND on the substrate BP is within the range of the orthographic projection of the corresponding insulated metal intermediate portion MMY on the substrate BP. In this way, in the prepared display panel PNL, the insulated metal block MM covers the outer edge of the corresponding pixel electrode AND.

In one embodiment of the present disclosure, when patterning the insulated metal material layer MMX to form the insulated metal intermediate portion MMY, the insulated metal intermediate portion MMY can completely cover the corresponding pixel electrode AND, such as covering the upper surface (the surface away from the substrate BP) of the corresponding pixel electrode AND and covering each edge of the pixel electrode AND. In this way, the insulated metal intermediate portion MMY protects the surface and edge sides of the pixel electrode AND, and the stability of the edges of the pixel electrode AND can be ensured to prevent the insulated metal material layer MMX from causing the pixel electrode AND to be etched during the patterning operation, especially to avoid the lateral etching of the pixel electrode AND. Optionally, the patterning operation of the insulated metal material layer MMX and the patterning operation of the pixel electrode material layer ANDLX can use different masks to ensure that the insulated metal intermediate portion MMY covers the corresponding pixel electrode AND.

Of course, in other embodiments of the present disclosure, the same mask plate can be used in the patterning operation of the pixel electrode material ANDLX and the insulated metal material layer MMX, and the insulated metal intermediate portion MMY can be made to cover the corresponding pixel electrode AND by controlling the exposure intensity, photoresist thickness, etc.

Of course, in other embodiments of the present disclosure, the formed insulated metal intermediate portion MMY may not cover the corresponding pixel electrode AND, for example, the shape of the insulated metal intermediate portion MMY may be the same as the shape of the pixel electrode AND (the two are completely overlapped) or the size of the insulated metal intermediate portion MMY may be smaller than the corresponding pixel electrode AND, as long as it does not interfere with the formation of the pixel bottom opening HHB and the insulated lateral slot CG. Further, a heat treatment can be applied to the pixel electrode AND to crystallize the pixel electrode AND before forming the insulated metal intermediate portion MMY, so as to reduce the damage to the pixel electrode AND during the formation of the insulated metal intermediate portion MMY, especially to avoid the damage to the lateral side of the pixel electrode AND.

Optionally, in this embodiment, the insulated metal material layer MMX may include a layer of metal or may include multiple layers of metal.

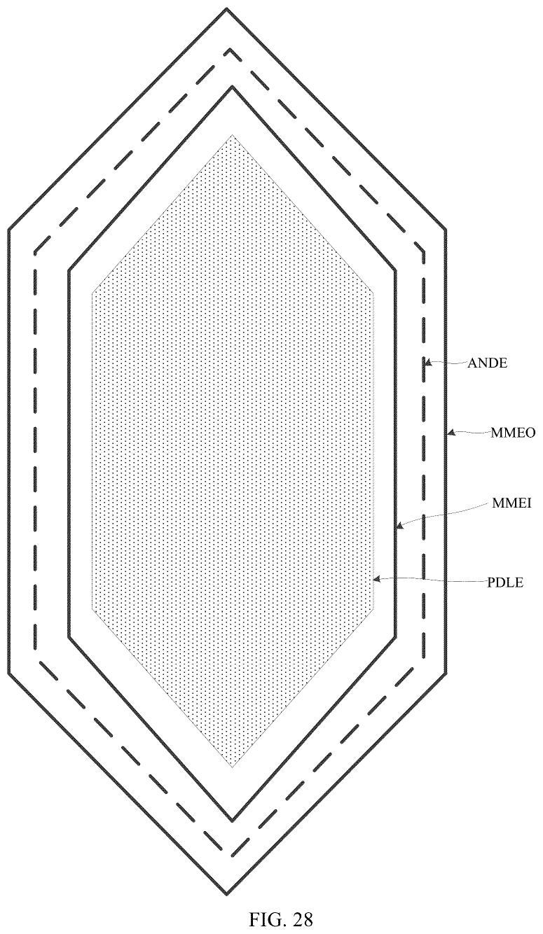

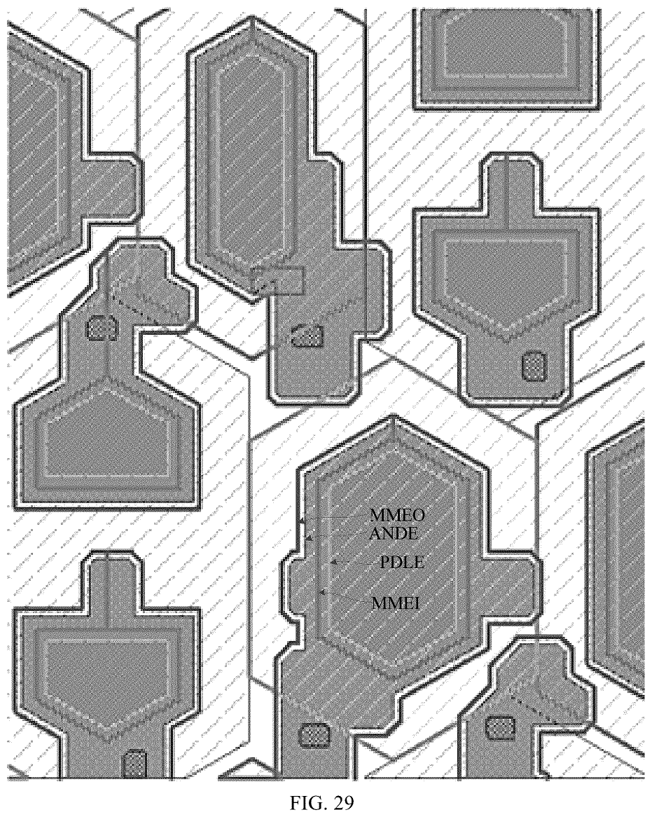

Step S430, referring to FIG. 25, forming the pixel definition layer PDL on a side of the insulated metal intermediate portion MMY away from the substrate BP, the pixel definition layer PDL having a pixel top opening HHA that exposes part of the insulated metal intermediate portion MMY. In FIG. 26, FIG. 28 and FIG. 29, the inner edge of the pixel definition layer PDL, i.e., the edge of the lower opening of the pixel top opening HHA (the opening close to the substrate BP), is illustrated by the edge PDLE. The orthographic projection of the lower opening of the pixel top opening HHA on the substrate BP is within the orthographic projection of the corresponding pixel electrode AND on the substrate BP, and within the orthographic projection of the corresponding insulated metal intermediate portion MMY on the substrate BP.

Step S440, referring to FIG. 26, etching the exposed part of the insulated metal intermediate portion MMY using the pixel definition layer PDL as a mask, and forming a pixel bottom opening HHB and the insulated lateral slot CG that expose at least part of the pixel electrode AND, the insulated lateral slot CG being interconnected to the pixel bottom opening HHB and surrounding the pixel bottom opening HHB. Thus, the insulated metal intermediate portion MMY is etched to form the insulated metal block MM, each insulated metal block MM corresponds to each pixel electrode AND, and each insulated metal block MM serves as at least part of the insulated metal layer MML. The pixel bottom opening HHB and the pixel top opening HHA together form the pixel opening H, and thus, the insulated metal block MM and the pixel definition layer PDL form the pixel opening HH that exposes at least part of the corresponding pixel electrode AND, and the insulated metal block MM also forms the insulated lateral slot CG surrounding the pixel opening HH.

Referring to FIG. 26, the part of the insulated metal intermediate portion MMY exposed by the pixel top opening HHA is completely etched. In addition, the part of the insulated metal intermediate portion MMY covered by the pixel definition layer PDL is also partially etched, causing the insulated metal intermediate portion MMY to shrink inward, and the space formed after the shrinkage is the insulated lateral slot CG. Referring to FIG. 26, there is a space between the inner edge (represented by the edge MMEI in FIG. 26) of the insulated metal block MM and the edge (represented by the edge PDLE in FIG. 26) of the pixel definition layer PDL at the pixel top opening HHA.

In one example, the insulated metal intermediate portion MMY may be wet etched and continued to be etched after the insulated metal intermediate portion MMY exposes the pixel electrode AND to cause the remaining insulated metal intermediate portion MMY to shrink to within the coverage of the pixel definition layer PDL to form the insulated lateral slot CG. Thus, the pixel definition layer PDL is overhung above the insulated lateral slot CG.

In one example, before etching the insulated metal intermediate portion MMY, the method for preparing the display panel PNL may also include performing a heat treatment on the pixel electrode AND. For example, the driver substrate BPP with the pixel electrode AND can be treated by an OVEN process, so that the ITO of the pixel electrode AND can be crystallized and the etch resistance of the ITO can be improved. The surface of the pixel electrode AND is not damaged by the etching solution during the wet etching of the insulated metal intermediate portion MMY, thus ensuring the luminous performance of the OLED.

Step S450, referring to FIG. 27, forming the electroluminescence layer EML and the common electrode layer COML sequentially on a side of the pixel definition layer PDL away from the substrate BP, the thickness of the electroluminescence layer EML being equal to or greater than a thickness of the insulated metal material layer MMX. Referring to FIG. 27, when the electroluminescence layer EML is deposited in the pixel bottom opening HHB, part of the material of the electroluminescence layer EML is deposited into the insulated lateral slot CG and the pixel definition layer PDL is overhanging above the insulated lateral slot CG, which causes at least part of the material layers of the electroluminescence layer EML to break off at the inner edge of the pixel definition layer PDL (i.e., the edge represented by the edge PDLE in FIG. 26, which is the edge of the lower opening of the top opening HHA, i.e., the edge of the pixel opening HH close to the substrate BP). That is, at least part of the film layers of the electroluminescence layer EML is broken at the area EEA in FIG. 27. In this way, crosstalk and light emission beyond the light-emitting definition area due to lateral current leakage between different OLEDs can be reduced.

Optionally, referring to FIG. 26, the thickness of the electroluminescence layer EML is greater than the thickness of the insulated lateral slot CG, which prevents the common electrode layer COML from sinking into the pixel bottom opening HHB, thus avoiding the breakage of the common electrode layer COML and ensuring the electrical continuity of the common electrode layer COML.

The embodiments of the present disclosure also provide a display device, which includes any of the display panels described in the above-mentioned display panel embodiments. The display device may be a smartphone screen, a smartwatch screen, or another type of display device. Since the display device includes any of the display panels described in the above-mentioned display panel embodiments, it has the same beneficial effects, and will not be repeated herein.

It should be noted that although the steps of the method for preparing the display panel in the present disclosure are shown in the accompanying drawings in a particular order, it is not required or implied that the steps must be performed in that particular order or that all of the steps shown must be performed to achieve the desired result. Additionally or alternatively, certain steps may be omitted, multiple steps may be combined into a single step, and/or a single step may be decomposed into multiple steps, etc.

Other embodiments of the present disclosure will be readily apparent to those skilled in the art upon consideration of the specification and practice of the content disclosed herein. This application is intended to cover any variation, use, or adaptation of the present disclosure that follows the general principles of the present disclosure and includes commonly known or customary technical means in the art not disclosed herein. The specification and embodiments are to be considered exemplary only, and the true scope and spirit of the disclosure is indicated by the appended claims.

1. A display panel, comprising a substrate, a driver layer and a pixel layer stacked in sequence, wherein the pixel layer comprises a pixel electrode layer, an insulated metal layer, a pixel definition layer, an electroluminescence layer and a common electrode layer stacked in sequence on a side of the driver layer away from the substrate;
wherein the pixel electrode layer comprises a pixel electrode, and the insulated metal layer comprises an insulated metal block corresponding to the pixel electrode; the insulated metal block and the pixel definition layer are provided with a pixel opening that exposes the corresponding pixel electrode; and an insulated lateral slot that surrounds the pixel opening and opens at the pixel opening, is provided between the insulated metal block and the pixel opening; and
wherein the electroluminescence layer covers the pixel opening, and a thickness of the electroluminescence layer in a direction perpendicular to the substrate is equal to or greater than a thickness of the insulated metal block.

2. The display panel according to claim 1, wherein an outer edge of the pixel electrode is flush with an outer edge of the corresponding insulated metal block.

3. The display panel according to claim 1, wherein the insulated metal block covers an outer edge of the corresponding pixel electrode.

4. The display panel according to claim 1, wherein the thickness of the insulated metal block ranges from 100 to 1000 Å.

5. The display panel according to claim 1, wherein the insulated metal block comprises a metal layer.

6. The display panel according to claim 1, wherein the insulated metal block comprises a first metal layer and a second metal layer stacked in sequence on a side of the pixel electrode away from the substrate, a metal activity of the second metal layer being weaker than a metal activity of the first metal layer; and
wherein the second metal layer protrudes from the first metal layer at an edge of the insulated metal block close to the insulated lateral slot.

7. The display panel according to claim 1, wherein a material of a surface of the pixel electrode layer away from the substrate is a conductive metal oxide.

8. The display panel according to claim 1, wherein the electroluminescence layer comprises a first organic light-emitting layer, a charge generation layer and a second organic light-emitting layer stacked in sequence on a side of the pixel electrode away from the substrate; and
wherein the charge generation layer is discontinuous at an edge of the pixel opening close to the substrate.

9. The display panel according to claim 1, wherein the insulated metal block is in a closed annular structure; and an orthographic projection of the pixel opening corresponding to the pixel electrode on the substrate, is within an orthographic projection of an inner cavity of the insulated metal block corresponding to the pixel electrode on the substrate.

10. A display device, comprising a display panel, wherein the display panel comprises: a substrate, a driver layer and a pixel layer stacked in sequence;
wherein the pixel layer comprises a pixel electrode layer, an insulated metal layer, a pixel definition layer, an electroluminescence layer and a common electrode layer stacked in sequence on a side of the driver layer away from the substrate;
wherein the pixel electrode layer comprises a pixel electrode, and the insulated metal layer comprises an insulated metal block corresponding to the pixel electrode; the insulated metal block and the pixel definition layer are provided with a pixel opening that exposes the corresponding pixel electrode; and an insulated lateral slot that surrounds the pixel opening and opens at the pixel opening, is provided between the insulated metal block and the pixel opening; and
wherein the electroluminescence layer covers the pixel opening, and a thickness of the electroluminescence layer in a direction perpendicular to the substrate is equal to or greater than a thickness of the insulated metal block.

11. A method for preparing a display panel, comprising:
forming a driver layer on a side of a substrate; and
forming a pixel layer on a side of the driver layer away from the substrate, the pixel layer comprising a pixel electrode layer, an insulated metal layer, a pixel definition layer, an electroluminescence layer and a common electrode layer stacked in sequence on the side of the driver layer away from the substrate;
wherein the pixel electrode layer comprises a pixel electrode, and the insulated metal layer comprises an insulated metal block corresponding to the pixel electrode; the insulated metal block and the pixel definition layer are provided with a pixel opening that exposes the corresponding pixel electrode; an insulated lateral slot that surrounds the pixel opening and opens at the pixel opening, is provided between the insulated metal block and the pixel opening; and the electroluminescence layer covers the pixel opening, and a thickness of the electroluminescence layer in a direction perpendicular to the substrate is equal to or greater than a thickness of the insulated metal block.

12. The method for preparing the display panel according to claim 11, wherein forming the pixel layer on the side of the driver layer away from the substrate, comprises:
forming a pixel electrode material layer and an insulated metal material layer sequentially on the side of the driver layer away from the substrate;
patterning the pixel electrode material layer and the insulated metal material layer to form a pixel electrode and an insulated metal intermediate portion corresponding to and stacked with the pixel electrode;
forming the pixel definition layer on a side of the insulated metal intermediate portion away from the substrate, the pixel definition layer having a pixel top opening that exposes part of the insulated metal intermediate portion;
etching the exposed part of the insulated metal intermediate portion using the pixel definition layer as a mask, and forming a pixel bottom opening and the insulated lateral slot that expose at least part of the pixel electrode, the insulated lateral slot being interconnected to the pixel bottom opening and surrounding the pixel bottom opening; and
forming the electroluminescence layer and the common electrode layer sequentially on a side of the pixel definition layer away from the substrate, the thickness of the electroluminescence layer being equal to or greater than a thickness of the insulated metal material layer.

13. The method for preparing the display panel according to claim 11, wherein forming the pixel layer on the side of the driver layer away from the substrate, comprises:
forming the pixel electrode layer on the side of the driver layer away from the substrate, the pixel electrode layer comprising the pixel electrode;
forming an insulated metal intermediate portion corresponding to the pixel electrode on a side of the pixel electrode layer away from the substrate, the insulated metal intermediate portion covering the corresponding pixel electrode;
forming the pixel definition layer on a side of the insulated metal intermediate portion away from the substrate, the pixel definition layer having a pixel top opening that exposes part of the insulated metal intermediate portion;
etching the exposed part of the insulated metal intermediate portion using the pixel definition layer as a mask, and forming a pixel bottom opening and the insulated lateral slot that expose at least part of the pixel electrode, the insulated lateral slot being interconnected to the pixel bottom opening and surrounding the pixel bottom opening; and
forming the electroluminescence layer and the common electrode layer sequentially on a side of the pixel definition layer away from the substrate, the thickness of the electroluminescence layer being equal to or greater than a thickness of the insulated metal intermediate portion.

14. The method for preparing the display panel according to claim 12, wherein etching the exposed part of the insulated metal intermediate portion using the pixel definition layer as the mask, comprises:
performing wet etching on the insulated metal intermediate portion, and continuing etching the the insulated metal intermediate portion after the insulated metal intermediate portion exposes the pixel electrode until remaining insulated metal intermediate portion shrinks to be within a coverage of the pixel definition layer to form the insulated lateral slot.

15. The method for preparing the display panel according to claim 12, wherein before etching the exposed part of the insulated metal intermediate portion using the pixel definition layer as the mask, the method further comprises:
performing heat treatment on the pixel electrode.

16. The method for preparing the display panel according to claim 12, wherein a thickness of the insulated metal intermediate portion ranges from 100 to 1000 Å.

17. The method for preparing the display panel according to claim 12, wherein the insulated metal intermediate portion comprises a metal layer.

18. The method for preparing the display panel according to claim 12, wherein the insulated metal intermediate portion comprises a first metal layer and a second metal layer stacked in sequence on a side of the pixel electrode away from the substrate, a metal activity of the second metal layer being weaker than a metal activity of the first metal layer; and
when the exposed part of the insulated metal intermediate portion is etched using the pixel definition layer as the mask, the insulated metal intermediate portion is patterned as the insulated metal block; and the second metal layer protrudes from the first metal layer at an edge of the insulated metal block close to the insulated lateral slot.

19. The method for preparing the display panel according to claim 12, wherein the electroluminescence layer comprises a first organic light-emitting layer, a charge generation layer and a second organic light-emitting layer stacked in sequence on a side of the pixel electrode away from the substrate; and
when the electroluminescence layer is formed on a side of the pixel definition layer away from the substrate, the charge generation layer is discontinuous at an edge of the pixel opening close to the substrate.

20. The display device according to claim 10, wherein the insulated metal block comprises a first metal layer and a second metal layer stacked in sequence on a side of the pixel electrode away from the substrate, a metal activity of the second metal layer being weaker than a metal activity of the first metal layer; and
wherein the second metal layer protrudes from the first metal layer at an edge of the insulated metal block close to the insulated lateral slot.
